(19) United States
(12) Patent Application Publication
(10) Pub. No.: US 2026/0304005 A1
(43) Pub. Date: Oct. 1, 2026

(54) ADAPTIVE GAIN COMPARATOR FOR IMAGE SENSORS

(71) Applicant: SEMICONDUCTOR COMPONENTS INDUSTRIES, LLC, Scottsdale, AZ (US)

(72) Inventor: Shankar RAMAKRISHNAN, Bangalore (IN)

(73) Assignee: SEMICONDUCTOR COMPONENTS INDUSTRIES, LLC, Scottsdale, AZ (US)

(21) Appl. No.: 19/443,668

(22) Filed: Jan. 8, 2026

Related U.S. Application Data
(60) Provisional application No. 63/779,840, filed on Mar. 28, 2025.

(51) Int. Cl. H04N 25/78; H03M 1/18; H04N 25/51

(52) U.S. Cl. CPC H04N 25/78; H03M 1/18; H04N 25/51

(57) ABSTRACT

Systems, devices, and methods are described for analog-to-digital (AD) conversion of a pixel output signal. An image sensor may include readout circuitry having adaptive-gain AD conversion circuitry selectable to operate with a normal or reverse readout. Various embodiments may include an AD converter (ADC) operable to perform adaptive-gain normal readout, converting the pixel reset value prior to the image value, and to perform a reverse readout. The adaptive-gain ADC may include a first comparison stage having an adaptive gain circuit, and a second comparison stage for comparing an output of the first stage with a threshold voltage. Some embodiments may include the first comparison stage coupled on a column line between the pixel output and a column line current source, and may include a column line switch operable to maintain the column line current source in a suitable operating condition.

### CROSS-REFERENCE TO RELATED APPLICATIONS

This application claims the benefit of U.S. Provisional Patent Application No. 63/779,840, filed Mar. 28, 2025, the entire contents of which are incorporated herein by reference.

### BACKGROUND

This application relates generally to image sensors and, more particularly, to adaptive-gain readout and reverse readout of pixels of an image sensor.

Image sensors may contain an array of pixels which are readout out by readout circuitry. The pixels may contain a photodiode (PD) configured to convert incident photons into electrical charge, and an output node such as a floating diffusion node which drives an output signal of the pixel. The pixel may be operated to provide a reset voltage level and image voltage level to the readout circuitry. The reset voltage level may indicate the voltage at the output node of the pixel after a pixel reset operation, and the image voltage level may indicate the amount of incident photons received by the pixel during an integration period. The readout circuitry may include one or more analog-to-digital converters (ADC's) to convert the analog voltage level to a digital representation.

Read noise, dynamic range (DR), and power consumption are often important parameters that determine the effectiveness of image sensors, such as complementary metal-oxide-semiconductor (CMOS) image sensors. Imaged scenes may include a variety of lighting conditions, including very low light and very bright light in a same scene, which can be challenging for read noise and DR. Image sensors may therefore be designed to apply varying gains to the pixel output to improve read noise and DR.

However, there is often a tradeoff between read noise, DR, and power consumption. For example, to achieve a low read noise, a high analog gain may be used, which may reduce the DR of the first readout of the pixel because the ADC can saturate at a fraction of the pixel's linear full well (LFW) capacity. In some cases, column amplifiers may be used to amplify the pixel output, which may result in an additional source of noise and/or power. Adaptive gain may be used to maintain some DR, but this may result in more complicated designs that are more costly to implement and/or require more power. It is additionally more difficult to enable image sensors that require both normal readout modes, where the reset voltage is converted prior to the image voltage, and reverse readout modes, where the image voltage is converted prior to the reset voltage, while also providing adaptive gain.

It would therefore be desirable to provide improved systems, devices, and methods for adaptive gain analog-to-digital conversion.

### BRIEF DESCRIPTION OF DRAWING FIGURES

FIG. 1 is a block diagram of an exemplary image sensor, according to various embodiments.

FIG. 2 representatively illustrates an exemplary pixel coupled with a readout circuitry, according to various embodiments.

FIG. 3 representatively illustrates an exemplary analog-to-digital (ADC) circuit having a first and second comparison stage, according to various embodiments.

FIG. 4 is a timing diagram illustrating exemplary operations of the ADC circuit in a normal readout mode, according to various embodiments.

FIG. 5 is a timing diagram illustrating exemplary operations of the ADC circuit in a reverse readout mode, according to various embodiments.

### BRIEF SUMMARY

Various embodiments relate to systems, devices, and methods for performing adaptive-gain readout and/or reverse readout of image sensor pixels.

In various embodiments, an image sensor may include a pixel; a pixel output line coupled to the pixel; and an analog-to-digital converter (ADC) coupled to the pixel output line, wherein the ADC is reconfigurable to operate in a normal readout mode and a reverse readout mode, wherein the ADC comprises: a first comparison stage comprising an adaptive gain circuit coupled with the pixel output line and a ramp voltage signal, wherein the first comparison stage is operable to generate a first output signal in response to the ramp voltage signal and a pixel output value from the pixel output line; a second comparison stage operable to receive the first output signal and generate a second output signal based on a comparison of the first output signal to a threshold voltage level; and a counter controllable according to the second output of the second comparison stage.

In various embodiments, an analog-to-digital converter (ADC) coupled with a pixel via a pixel output line may include a first comparison stage, comprising: a first output; and an adaptive gain circuit coupled with a voltage ramp signal, the pixel output line, and the first output, wherein: the adaptive gain circuit comprises a high-gain transistor, a low-gain transistor, and a ramp attenuation circuit coupled with the voltage ramp signal and the high-gain transistor; the adaptive gain circuit is operable to compare, using one of the low-gain transistor or high-gain transistor, the voltage ramp signal with a pixel output value on the pixel output line; and the first comparison stage is operable to provide a first output signal on the first output based on the comparison by the adaptive gain circuit; a second comparison stage coupled with the first output, the second comparison stage comprising a second output, wherein the second comparison stage is operable to provide a second output signal on the second output based on a comparison of the first output signal to a threshold voltage; and a counter controllable according to the second output.

In various embodiments, a method for converting a pixel output signal of a pixel may include receiving, by a first comparison stage of an analog-to-digital converter (ADC), the pixel output signal and a ramp voltage signal; selecting a gain level of the first comparison stage; comparing, by the first comparison stage and according to the selected gain level, the pixel output signal to the ramp voltage signal; generating a first output signal based on the comparison of the first comparison stage; comparing, by a second comparison stage of the ADC, the first output signal to a threshold voltage level; generating, by the second comparison stage, a second output signal based on the comparison by the second comparison stage; and controlling a counter based on the second output signal.

These and other examples are described in increasing detail below.

### DETAILED DESCRIPTION

The following detailed description is intended to provide several examples that will illustrate the broader concepts that are set forth herein, but it is not intended to limit the invention or the application and uses of the invention. Furthermore, there is no intention to be bound by any theory presented in the preceding background or the following detailed description.

According to various embodiments, adaptive gain readout sensor devices and methods are provided that beneficially reduce power consumption, improve performance, and decrease image sensor cost. Exemplary image sensor devices and methods may be reconfigurable into a normal readout mode having adaptive gain and into a reverse readout mode. Exemplary image sensor devices and methods may determine to use a low gain or high gain pixel readout in the normal readout mode, depending on pixel output values determined by illumination levels. According to various embodiments, exemplary image sensor devices and methods may use an analog-to-digital converter adapted to provide adaptive analog gain, without the use of a column amplifier. Exemplary image sensor devices and methods may result in low incremental power consumption. In addition, various embodiments may be applied with single slope or other ramp-based ADC's.

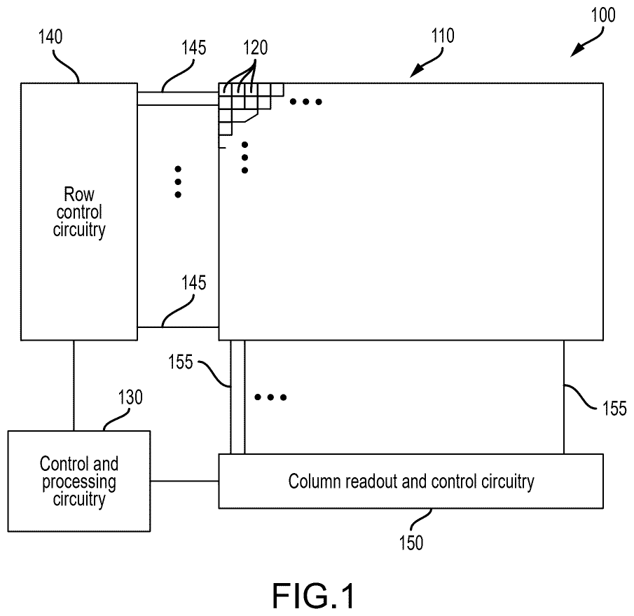

FIG. 1 illustrates a block diagram of an exemplary image sensor 100. In some embodiments, the configuration of the image sensor, the arrangement of various components therein, and the operation of the various components may be similar, in some aspects, to that which is described with respect to U.S. patent application Ser. No. 18/056,755, which is incorporated herein by reference. The embodiments described herein, however, may be applied to other configurations of image sensors, pixel arrays, pixels, and the like. In some embodiments, the image sensor 100 may be implemented as a semiconductor device on a single substrate, stacked substrates, system-on-chip, or the like.

In some embodiments, the image sensor 100 may include a pixel array 110 having multiple image sensor pixels 120. The pixels 120 may be arranged in any suitable manner. For example, the pixels 120 may be arranged in groups, for example in a stacked sensor arrangement. In some embodiments, the pixels 120 may be arranged in rows and columns. The image sensor 100 may further include control and processing circuitry 130, which may be referred to herein as control circuitry 130.

The control circuitry 130 may be coupled with row control circuitry 140 and column readout and control circuitry 150, which may be referred to herein as readout circuitry 150. The control circuitry 130 may provide timing controls for the row control circuitry 140. Based on the timing controls, the row control circuitry 140 may provide, over one or more conductive row control paths 145, corresponding row control signals such as reset, row select, charge transfer, dual conversion gain, readout, and/or any other suitable pixel control signals to each row of pixels 120.

In some embodiments, the image sensor 100 may include conductive column lines 155 coupled to each column of pixels 120 in the pixel array 110. The column lines 155 may be used for reading out signals from the pixels 120 and for supplying bias currents and/or bias voltages to the pixels 120. In some embodiments, a pixel readout operation may include selecting and controlling a pixel row in the pixel array 120 using the row control circuitry 140 and reading out, using the column lines 155, the pixel values generated by the pixels 120 in the selected row. The pixel values may be analog values, for example an analog voltage or current. The column lines 155 may be referred to as pixel output lines 155.

The readout circuitry 150 may control the operation, including readout, of the pixels 120 and may receive the pixel output values from the column lines 155. In some embodiments, the pixel output values may include reset values, image signal values, and/or the like. The readout circuitry 150 may include memory circuitry for storing, whether permanently or impermanently, calibration signals such as reset level signals and reference level signals, and/or pixel signals read from the pixel array 120. The readout circuitry 150 may include amplifier circuitry, analog-to-digital conversion (ADC) circuitry, bias circuitry, control circuitry, and/or other circuitry coupled to the pixel columns of the pixel array 110.

The amplifier circuitry may amplify the pixel value readout from the pixel 120, and the ADC circuitry may convert the analog pixel values to digital pixel values. The readout circuitry 150 may provide the digital pixel values to the control circuitry 130 and/or other storage and processing circuitry of the image sensor 100 for further processing. The additional processing may include converting the digital pixel values to image data, performing high dynamic range (HDR) processing by appropriate combining multiple exposures and/or differently-gained pixel readouts, and/or the like.

In some cases, the amplifier circuitry may include a column amplifier configured to amplify or adaptively amplify the pixel output signal. Advantageously, various embodiments according to the present technology may enable adaptive gain readout of the pixel 120 without the use of column amplifiers. For example, various embodiments may include an adaptive-gain ADC.

One or more of the control circuitry 130, row control circuitry 140, and/or readout circuitry 150 may include associated storage circuitry configured to store instructions, such as firmware, software, or the like, executable by a processing component of the respective control circuitry 130, 140, 150. The associated storage circuitry may include, for example, non-transitory computer-readable media. The stored instructions may, when executed by the respective processing component, implement one or more processes described herein, for example one or more timing diagrams for controlling the readout circuitry 150 to perform a pixel value conversion, standard readout, reverse readout, and/or the like.

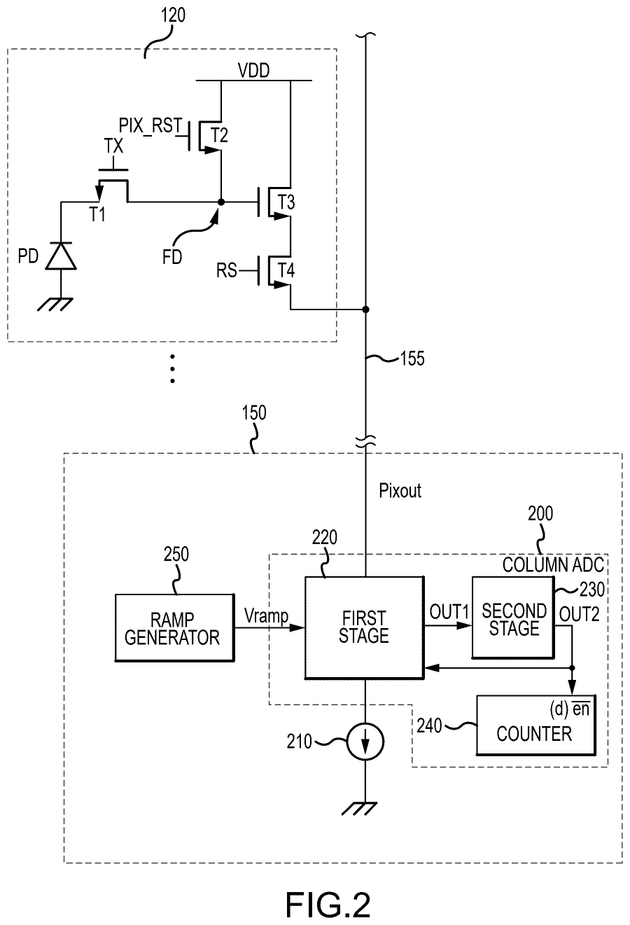

FIG. 2 representatively illustrates an exemplary arrangement of a pixel 120 coupled with a readout circuitry 150 via a pixel output line 155, according to various embodiments. The pixel 120 may include a photosensitive device such as a photodiode PD and a charge transfer transistor such as charge transfer transistor T1 having a first source-drain terminal coupled to photodiode PD, a second source-drain terminal coupled to floating diffusion node FD, and a gate terminal configured to receive charge transfer control signal TX. The charge transfer transistor T1 may be referred to as a charge transfer gate, and the floating diffusion node FD may be referred to as a floating diffusion region.

The pixel 120 may further include a reset transistor T2 having a drain terminal coupled to a positive power supply line (e.g., a power supply terminal on which positive power supply voltage VDD is provided), a source terminal coupled to the floating diffusion node FD, and a gate terminal configured to receive a reset control signal PIX_RST. The terms “source” terminal and “drain” terminal, when referring to current-conducting terminals of a metal-oxide semiconducting transistor, can be used interchangeably and are sometimes referred to as “source-drain” terminals. For example, the drain terminal of the reset transistor T2 can be referred to as its first source-drain terminal, and the source terminal of the reset transistor T2 can be referred to as its second source-drain terminal, or vice versa.

The pixel 120 may also include a source follower transistor T3 having a drain terminal coupled to the positive power supply line, a gate terminal coupled to the floating diffusion node FD, and a source terminal. The source follower transistor T3 is sometimes simply referred to as a “source follower.” The pixel 120 may further include a row select transistor T4 having a drain terminal coupled to the source terminal of the source follower T3, a gate terminal configured to receive a row select control signal RS, and a source terminal coupled to a corresponding pixel output line 155. In the example of FIG. 2, transistors T1-T4 may all be n-type metal-oxide-semiconductor (NMOS) transistors. In other embodiments, at least some transistors T1-T4 can alternatively be implemented as p-type metal-oxide-semiconductor (PMOS) transistors. In yet other embodiments, the pixel 120 can optionally include four or more n-channel and/or p-channel transistors. Further, any number of pixels 120 may be coupled to the pixel output line 155 for readout. For example, the pixel output line 155 may be coupled to one or more pixels in a pixel column of the pixel 120, for example to one or more pixels in one or more rows of the pixel 120. The pixel output line 155 may be coupled with more than 10 pixels in a column of pixels, more than 100 pixels in the column, more than 1000 pixels in the column, and so on.

It will be understood that the exemplary pixel 120 of FIG. 2 is merely illustrative, and other embodiments may include pixels 120 having multiple photodiodes, anti-blooming circuitry, multiple gain conversion circuitry, one or more storage capacitors, mode switching circuitry, and/or the like. The readout circuitry 150 described herein, in particular the ADC, may be used with any number of suitable arrangements of a pixel 120, pixel array 110, and image sensor 100.

The pixel output line 155 may be coupled to a corresponding analog-to-digital converter (ADC) circuit 200 that is configured to convert an analog signal read out from a selected pixel 120 to a digital equivalent. The pixel output line 155 may also be coupled to a column line current source 210 that is configured to sink a relatively constant amount of current. The readout circuitry 150 may include the ADC circuit 200 and/or the column line current source 210. In some embodiments, the ADC circuit 200 may be a ramp analog-to-digital converter.

The ADC circuit 200 may include one or more comparison stages such as a first comparison stage 220 and a second comparison stage 230, and a counter circuit such as counter 240. The first comparison stage 220 may be configured to receive a voltage ramp signal Vramp from a voltage generator 250, and may be configured to generate a first output signal OUT1 to the second comparison stage 230. The second comparison stage may be configured to receive the first output signal OUT1, perform a comparison against a voltage reference, and generate a second output signal OUT2. The counter 240 may receive the second output signal OUT2. When the second output signal OUT2 is at a first value, the counter 240 is enabled and is allowed to keep counting. When the second output signal OUT2 is at a second value, the counter 240 is disabled and will stop counting. The final count value output by the counter 240 may be a function of the image signal read out from a selected pixel 120, a function of the combination of the sample-and-hold (SHS) and sample-and-hold reset (SHR) values obtained from the pixel 120, or the like.

In some embodiments, the first comparison stage 220 and/or second comparison stage 230 may include single-ended voltage comparison circuits. In contrast to single-ended voltage comparison circuits, differential voltage comparators include differential input transistors that typically result in higher noise levels and increased power consumption. Thus, relative to conventional differential comparators, the use of single-ended voltage comparison stages in the ADC circuit 200 may provide technical advantages and may reduce power consumption while minimizing the overall noise level of the ADC circuit 200. The first single-ended comparison stage 220 and the second single-ended comparison stage 230 may therefore be referred to as “low noise” comparison circuits.

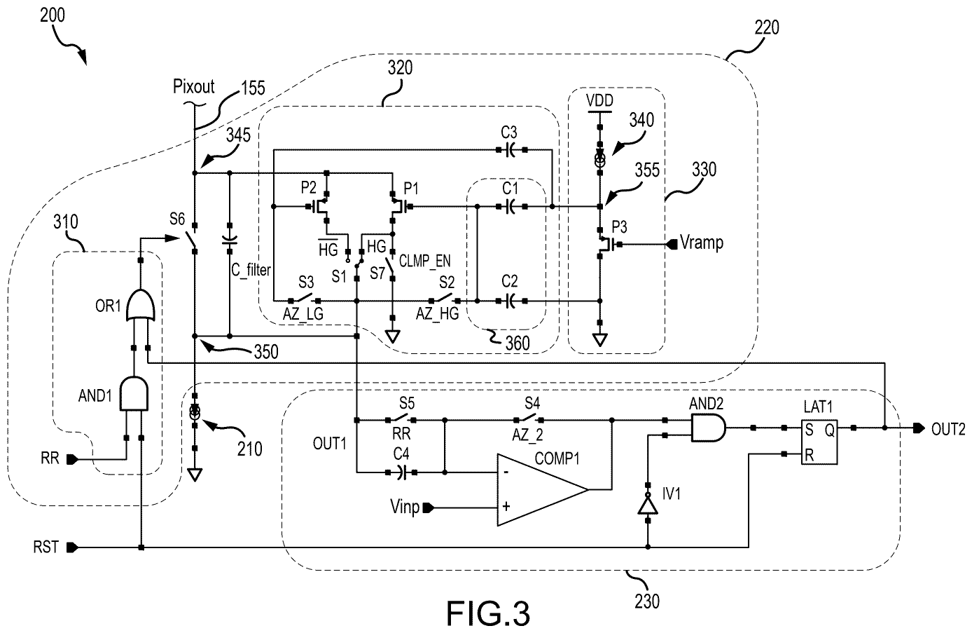

FIG. 3 representatively illustrates an exemplary arrangement of the ADC circuit 200, for example including the first comparison stage 220 and second comparison stage 230, according to various embodiments. In various embodiments, the ADC circuit 200 may be reconfigurable such that it can be selectively configured to operate with different functionality. For example, the ADC circuit 200 may be reconfigurable to operate in a first readout mode or a second readout mode, wherein a first selected configuration of the ADC circuit 200 may perform the first readout mode and a second selected configuration of the ADC circuit 200 may perform the second readout mode. The various configurations may include performing operations according to one or more control signals provided by the ADC circuit 200, readout circuitry 150, control circuitry 130, other circuitry in the image sensor 100, or the like. The first readout mode may include a normal readout mode having adaptive gain performed by the ADC circuit 200, and the second readout mode may include a reverse readout mode having a fixed gain performed by the ADC circuit 200. In some embodiments, the fixed gain of the reverse readout mode may be a unitary gain.

The normal readout mode, which may also be referred to as a forward readout, standard readout, and/or correlated double sampling (CDS), may include performing sample-and-hold reset (SHR) operations followed by sample-and-hold signal (SHS) operations. The SHR operations may provide a reset value for the pixel 120, and the SHS operations may provide a signal value, also referred to as an image value, for the pixel 120. The reverse readout mode may include performing the SHS operations followed by the SHR operations. In both modes of operation, a final pixel value representing the total actual incident light received by the pixel 120 during an integration period may be determined by subtracting the signal value from the reset value.

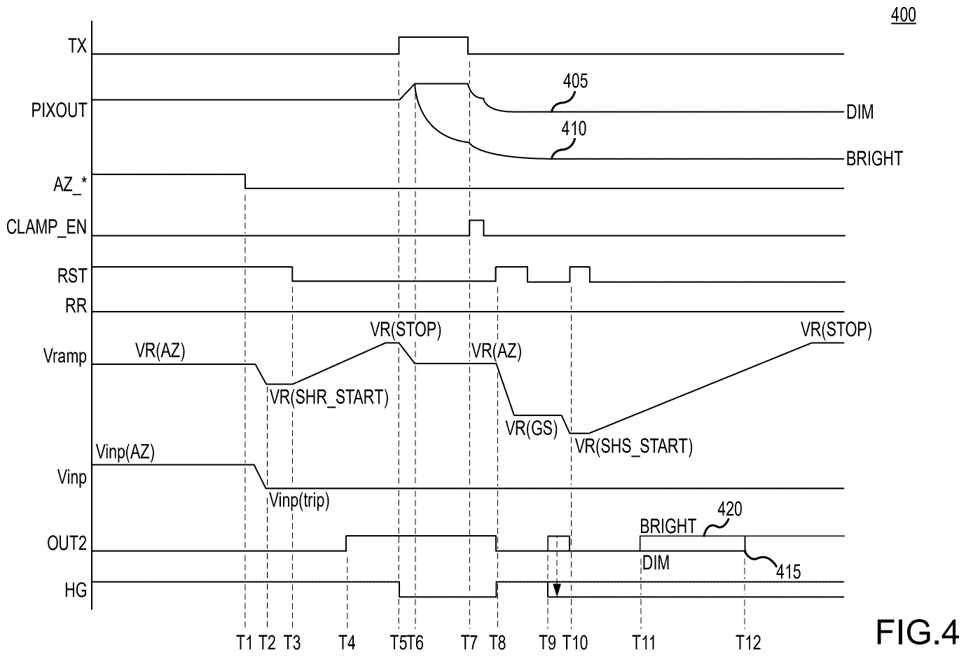

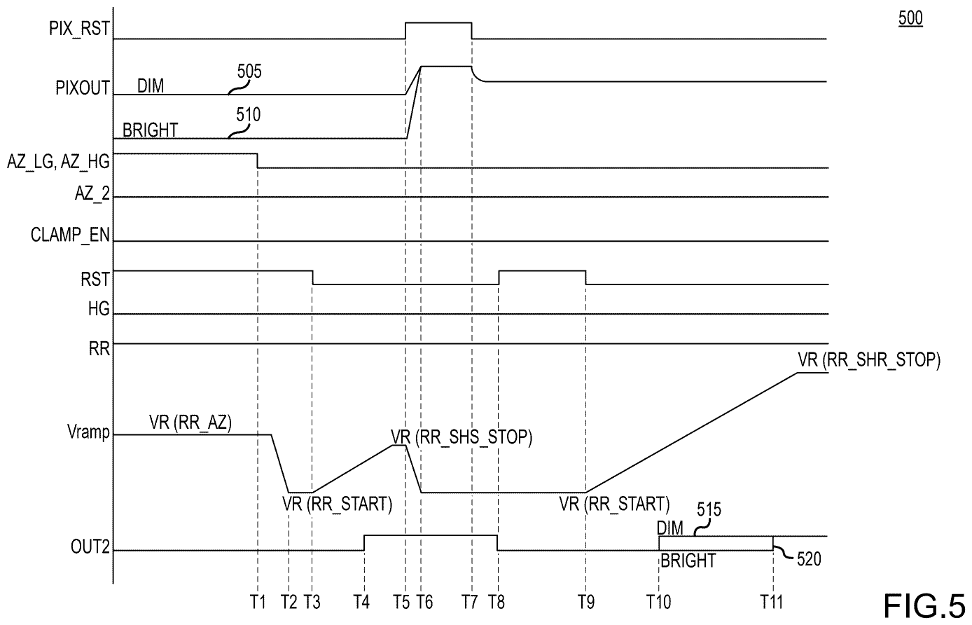

The SHR and SHS operations may each include operations to control and perform readout of the pixel 120 and operations to perform analog-to-digital conversion of the value obtained from the pixel 120. Exemplary operations will be illustrated in more detail below, for example as shown and described with respect to FIGS. 4 and 5. Advantageously, an ADC circuit 200 according to various embodiments may provide a low-noise, single-ended comparison in both a normal readout mode and a reverse readout mode, while also providing adaptive gain in the normal readout mode.

As shown in FIG. 3, the first comparison stage 220 may be coupled to the pixel output line 155 in series between the pixel 120 and the column line current source 210. The first comparison stage 220 may include a column line switch S6 coupled in series on the pixel output line 155, for example between nodes 345 and 350, and arranged to control a direct connection of the column line current source 210 with the pixel output line 155. In various embodiments, the column line current source 210 may be considered part of the ADC circuit 200, for example part of the first comparison stage 220. The ADC circuit 200, for example the first comparison stage 220, may include a column line level setting circuit 310 configured to control the column line switch S6. The column line level setting circuit 310 may control the column line switch S6 based on the read mode (normal readout or reverse readout), the current state of reset, and the state of the output of the second comparison stage 230. In some embodiments, the column line switch S6 may include an NMOS transistor and a PMOS transistor in parallel, forming a transmission gate. In other embodiments, the column line switch S6 may consist of a single transistor such as an NMOS only.

In some embodiments, the column line level setting circuit 310 may include a first AND gate AND1 and a first OR gate OR1. The first AND gate AND1 may receive, on a first input, a read mode signal RR that indicates the read mode. For example, the read mode signal RR may be a logic high or ‘1’ when performing the reverse readout operations, and a logic low or ‘0’ when performing the normal readout operations. The first AND gate AND1 may receive, on a second input, a reset signal RST that indicates when one or more components of the ADC circuit 200 should be reset. For example, the RST signal may indicate that the second comparison stage 230 output should be reset, de-asserted, or the like. In some embodiments, the RR and RST signals may be provided by control logic of the image sensor 100, for example by the control circuitry 130, readout circuitry 150, or the like. The first OR gate OR1 may receive, on a first input, the output of the first AND gate AND1 gate, and may receive, on a second input the second output signal OUT2 from the second comparison stage 230. The output of the first OR gate OR1 may control the column line switch S6, for example closing the column line switch S6 when the output of the first OR gate OR1 is logic high or ‘1’ and opening the column line switch S6 otherwise.

In some embodiments, the first comparison stage 220 may include an adaptive gain circuit 320 coupled in parallel with the column line switch S6 and a filter capacitor C_filter coupled in parallel with the column line switch S6, each for example coupled in series between nodes 345 and 350. The adaptive gain circuit 320 may be configured to receive the pixel value obtained from the pixel output line 155. The adaptive gain circuit 320 may be further configured to receive a ramping voltage signal, for example Vramp or based on Vramp. In some embodiments, first comparison stage 220 may include a ramp bias circuit 330 configured to provide the ramping voltage signal to the adaptive gain circuit 320. The adaptive gain circuit 320 may provide the first output signal OUT1 from the node 350.

In some embodiments, the ramp bias circuit 330 may include a ramp current source 340 coupled in series between a supply voltage and a transistor P3. In some embodiments, the supply voltage may be the same supply provided to the pixel array 110, for example VDD, or any other power supply that is suitable to support the voltage ramp range. The transistor P3 may have a first source-drain terminal, for example the source terminal, coupled to the ramp current source 340 at a node 355, and a second source-drain terminal coupled to a ground or other common voltage node. The gate of the transistor P3 may receive the Vramp signal from the voltage generator 250. The transistor P3 may be a PMOS transistor and may be arranged as a source follower, such that the voltage at node 355 follows the ramp voltage Vramp. The transistor P3 may provide a ramping voltage signal, while preventing loading of the Vramp signal by the adaptive gain circuit 320. In some alternative embodiments, the transistor P3 may be an NMOS transistor.

The filter capacitor C_filter may have a first terminal coupled to node 345 and a second terminal coupled to node 350. Arranged in this way, the capacitor C_filter can be configured to filter out any wide-band and/or thermal noise associated with the column line switch S6. The capacitor C_filter can also be used to limit the slew rate at node 350 by absorbing any transient currents or other effects. The capacitor C_filter is optional and can be omitted to help reduce circuit area. The filter capacitor C_filter can be 10 fF, 20 fF, 10-50 fF, 50-100 fF, less than 50 fF, more than 100 fF, several hundred femtofarads, or other capacitance to provide the desired filtering capabilities.

In some embodiments, the adaptive gain circuit 320 may include a transistor P1 coupled in parallel with a transistor P2. In some embodiments, the transistor P1 and transistor P2 may be the same size or approximately the same size. In some embodiments, the transistor P1 and transistor P2 may be different sizes. Each of the transistor P1 and transistor P2 may have a first source-drain terminal, for example their source terminals, coupled with the node 345. The adaptive gain circuit 320 may include a gain select switch S1 having its fixed terminal coupled with the node 350 and its switching terminal coupled with the second source-drain terminals of the transistors P1 and P2. The gain select switch S1 may be controlled by a HG (high gain) signal. For example, the gain select switch S1 may be controllable to couple the drain of the transistor P1 to the node 350 when the HG signal is logic ‘1’ or high (e.g., asserted), and to couple the drain of transistor P2 to the node 350 when the HG signal is logic ‘0’ or low (e.g., de-asserted). In some embodiments, the transistor P1 and/or transistor P2 may be PMOS transistors. In some alternative embodiments, the transistor P1 and/or transistor P2 may be NMOS transistors.

The gate terminal of the transistor P1 may be coupled to a ramp attenuation circuit, for example coupled to the output of a voltage divider 360 of the adaptive gain circuit 320. The gate terminal of the transistor P2 may be coupled to the node 355. Consequently, in some embodiments, the gate of the transistor P1 may receive an attenuated version of the ramp voltage from the ramp bias circuit 330, while the gate terminal of the transistor P2 may receive the unattenuated ramp voltage. In this arrangement, the transistor P1 may operate to compare the pixel signal on the pixel output line 155 to the attenuated Vramp signal to effectuate a high-gain (HG) mode, and the transistor P2 may operate to compare the pixel signal on the pixel output line 155 to the Vramp signal in a low-gain (LG) mode. In other words, analog gain may be realized using the transistor P1 by attenuating the voltage ramp. In some alternative embodiments, the gate terminal of transistor P2 may receive an attenuated ramp voltage signal that is attenuated less than the signal received by the gate of the transistor P1. The transistor P1 may be referred to as the high-gain transistor, and the transistor P2 may be referred to as the low-gain transistor.

In some embodiments, the voltage divider 360 may comprise a capacitor voltage divider, for example having a capacitor C1 having a first terminal coupled with the node 355 and a second terminal coupled with a capacitor C2. The capacitor C2 may have a first terminal coupled to the capacitor C1 and a second terminal coupled to the ground or the common voltage node. The gate of the transistor P1 may be coupled, for example AC coupled, to the node 355 through the capacitor C1. When the Vramp signal is changing, for example during a ramp period, the current from the ramp current source 340 will be divided between the transistor P3 and the capacitors C1 and C2.

The capacitors C1 and C2 may be of any suitable capacitance to perform the functions of a voltage divider and may be selected based on any desired ratio for the voltage divider. The capacitance of capacitors C1 and C2 may be optimized for noise performance, if desired. For example, if capacitor C2 has four times the capacitance of capacitor C1 then the gate of transistor P1 may receive a voltage that is one-fifth the voltage at node 355. Additionally, if the voltage at node 355 changes by 1 Volt (V) then the voltage at the terminal of transistor P1 changes by the attenuated amount. In some embodiments the gate of transistor P2 may be coupled, for example AC coupled, to node 355 using a capacitor C3. The first terminal of the capacitor C3 may be coupled to the gate of transistor P2, and the second terminal of the capacitor C3 may be coupled to the node 355.

The attenuation of the voltage at the gate of transistor P1 corresponds to a non-unitary gain for the ramp ADC 200. As described above, the transistor P2 may receive the full (unattenuated) ramp voltage of the Vramp signal or the voltage ramp of node 355. In this arrangement, the transistor P2 may provide a unitary or otherwise low gain for the ramp ADC 200. Consequently, the transistor P1 may be referred to as a high-gain (HG) transistor and the transistor P2 may be referred to as a low-gain (LG) transistor.

In some embodiments, the gate of transistor P2 may be coupled with the node 350 through a first autozero switch S3, and the gate of the transistor P1 may be coupled to the node 350 through a second autozero switch S2. The switch S3 may be used to perform auto-zeroing in a low-gain mode and may be referred to as the LG autozero switch S3, and the switch S3 may be used to perform auto-zeroing in a high-gain mode and may be referred to as the HG autozero switch S2. The LG autozero switch S3 may be controlled by a control signal AZ_LG, and the HG autozero switch S2 may be controlled by a control signal AZ_HG.

In some embodiments, the second source-drain terminal of the transistor P1 may be coupled to ground or another common voltage node through a clamp switch S7. The clamp switch S7 may be controlled by a clamp enable signal CLAMP_EN and may be used to provide a low impedance path to ground, for example to help pull the voltage on the pixel output line 155 down to the reset voltage level. This will help the pixel output line 155 settle faster at the end of the charge transfer phase if its voltage becomes higher than the reset level during the charge transfer phase due to feedthrough from the transfer gate T1 to the source follower T3 in FIG. 2.

Accordingly, the adaptive gain circuit 320 may provide, at node 350 as the first output signal OUT1, a voltage level dependent upon whether a high-gain mode and transistor P1 are selected for comparing the pixel value on the pixel output line 155 to the Vramp signal, or a low-gain mode and transistor P2 are selected for the comparison.

In some embodiments, the second comparison stage 230 may include a comparator COMP1 having a first input, for example an inverting input, configured to receive the first output signal OUT1, and a second input, for example a non-inverting input, configured to receive a threshold comparison voltage level Vinp. The second comparison stage 230 may include a comparison mode switch S5 coupled in series between node 350 and the first input of the comparator COMP1, and a capacitor C4 coupled in series between node 350 and the first input of the comparator COMP1. The comparison mode switch S5 and capacitor C4 may be coupled in parallel. The comparison mode switch S5 may be controlled by signal RR. The output of the comparator COMP1 may be coupled, through a comparator autozero switch S4, to the first input of the comparator COMP1. The comparator autozero switch S4 may be controlled by a control signal AZ_2.

The output of the comparator COMP1 may be coupled with a first input of a second AND gate AND2. A second input of the second AND gate AND2 may receive an inverted version of the RST signal, for example from an inverter IV1 coupled to receive the RST signal. The output of the second AND gate AND2 may be provided to a latching circuit such as latch LAT1. The latch LAT1 may, for example, be a positive feedback latch configured to provide a clean transition at its output. In some embodiments, the latch LAT1 may comprise a set-reset (SR) latch, the output of the second AND gate AND2 may be coupled with the set ‘S’ terminal of the latch LAT1, and the reset ‘R’ terminal of the latch LAT1 may be coupled to receive the RST signal. The output of the latch LAT1 may be provided from the ‘Q’ output of the SR latch. In some embodiments, the output of the latch LAT1 may provide the second output signal OUT2.

In some embodiments, the output of the latch LAT1 may be coupled to an enable input of the counter 240. When the output of the latch LAT1, for example the OUT2 signal, is at a first value, the counter 240 is enabled and is allowed to keep counting. When the output of the latch LAT1 is at a second value, the counter 240 is disabled and will stop counting. The final count value output by the counter 240 may be a function of the reset or image signal read out from a selected pixel 120 via the pixel output line 155. The final count value may also be a function of the gain mode of the ADC circuit 200, for example whether transistor P1 or transistor P2 is selected by the gain select switch S1.

For example, in some embodiments, while the ramp signal Vramp increases or decreases as the pixel 120 is reset, the counter 240 may count up or down from a reset value while monitoring the second output signal OUT2 and may stop counting in response to a change of state of the second output signal OUT2. The stopped count value may be an example of a digital reset value corresponding to the signal output by the pixel 120 in response to being reset. Further, while the ramp signal Vramp increases or decreases as the image signal is read out of the pixel 120, the counter 240 may count in the opposite direction, for example down or up respectively, while monitoring the second output signal OUT2 and may stop counting in response to a change of state of the second output signal OUT2. The stopped count value may be an example of a digital signal value corresponding to the image signal output by the pixel 120, for example corresponding to an accumulated charge in the pixel 120 due to receiving incident photons via the photodiode PD. This exemplary process may be used to perform correlated double sampling (CDS), where a normal readout is performed.

The operation of an ADC circuit 200 of the type described in connection with FIGS. 1-3 may be understood in conjunction with the timing diagrams of FIGS. 4 and 5. FIG. 4 is a timing diagram illustrating the operation of the ADC circuit 200 when the image sensor 100 performs a normal readout having SHR before SHS. FIG. 4 thus illustrates a method of performing an adaptive gain normal readout 400. Waveform TX represents the signal for controlling charge transfer transistor T1 (see FIG. 2). Waveform PIXOUT represents the voltage at the pixel output line 155. Waveform AZ_* represents the signals for activating the autozero switches S2, S3, and S4. Waveform CLAMP_EN represents the signal for activating the clamp switch S7. Waveform RST represents the reset control signal. Waveform RR represents the RR control signal indicating whether the ADC circuit 200 is operating in reverse readout mode. Waveform Vramp represents the ramp signal output from the ramp generator and/or the ramp signal provided by the ramp bias circuit 330, for example from node 355. Waveform Vinp represents the threshold voltage provided to the non-inverting input of the comparator COMP1. Waveform OUT2 represents the signal output by the second comparison stage 230, for example used to selectively enable and disable the counter 240. Waveform HG represents the HG control signal indicating whether the first comparison stage 220 is operating in a high-gain mode.

Prior to time T1, the autozero signals AZ_* may be asserted, for example set high, to turn on the HG autozero switch S2, LG autozero switch S3, and comparator autozero switch S4. At this time, the Vramp volage may be set to an autozero voltage level VR(AZ) that is greater than a first ramp start voltage VR(SHR_START). For example, the autozero voltage level VR(AZ) may be 100 mV greater than the first ramp start voltage VR(SHR_START). This is merely illustrative and other embodiments may use an autozero voltage level VR(AZ) 120 mV greater than VR(SHR_START), 150 mV greater than VR(SHR_START), 100-200 mV greater than VR(SHR_START), 50-100 mV greater than VR(SHR_START), 200-250 mV greater than VR(SHR_START), or other suitable amount of voltage greater than VR(SHR_START). The time period during which the autozero switches are turned on, for example prior to time T1, is sometimes referred to as the auto-zero phase.

At this time, the HG signal may be asserted so that gain select switch S1 selects transistor P1. In some embodiments, of the two transistors P1 and P2, only the transistor P1 is actively auto-zeroed because transistor P1 is on and transistor P2 is off. In some embodiments, the gate voltage of transistor P2 is forced to be the same as that of transistor P1. This can save time required for auto-zeroing and can be effective because transistor P1 and transistor P2 are typically fairly well matched. Autozeroing may allow the trip points to be independent of the transistor threshold voltage and/or the pixel reset level voltage because these may vary from device to device. At this time, the reset signal RST may be asserted so that the latch LAT1 is cleared, causing the second output signal OUT2 to be de-asserted, and column line switch S6 is turned off. The reverse readout signal RR may be de-asserted, for example kept low, the entire duration of the normal readout operations.

When the HG autozero switch S2 is turned on, transistor P1 becomes diode connected, the drain voltage of transistor P1 becomes PIXOUT minus the drop across transistor P1, the voltage at the gate of transistor P1 becomes PIXOUT minus the Vgs of transistor P1, and the voltage at node 355 remains the ramp voltage. The Vgs of transistor P1, which may be referred to herein as Vgs(P1), represents the gate-to-source voltage cross the transistor P1. The voltage across capacitor C1 is the difference between the ramp voltage and the voltage at the gate of the transistor P1, which depends on the Vgs of transistor P1. After autozero is complete, the voltage across the capacitor C1 remains as it was set during autozero. The Vgs for transistor P1 is based on the current flowing through the transistor P1 such that if Vramp increases then transistor P1 will conduct less and if Vramp decreases then transistor P1 will conduct more. That balance is set by the autozero operation, and sets the trip point to VR(AZ).

Each pixel 120 in the pixel array 110 may have a different reset value, for example 2.0 V, 2.05 V, 1.9 V, 1.85 V, and/or the like. Accordingly, the autozeroing of the ADC circuit 200 may be configured to allow it to determine a relative value between a reset value of a pixel 120 and the image value of the pixel 120. The reset value may be used as a reference, the comparator COMP1 may trip at different times for the reset and image PIXOUT signals, and the relative difference may be used to determine a final pixel value.

At this time, still prior to time T1, the comparator COMP1 may be autozeroed. The Vinp signal may be kept at some known voltage level Vinp(AZ). For example, with comparator autozero switch S4 on and comparison mode switch S5 off, the first output signal OUT1 is coupled with the inverting input of comparator COMP1 through capacitor C4, and the output of the comparator COMP1 is directly coupled with the inverting input, in some embodiments. During autozero, where the value of PIXOUT is at the pixel reset level, both inputs of the comparator COMP1 take on the value of Vinp(AZ), the first output signal OUT1 takes on the value of PIXOUT-Vgs(P1), and the voltage across the capacitor C4 becomes PIXOUT-Vgs(P1)-Vinp(AZ). Regardless of reset value of a particular pixel 120, each PIXOUT corresponding to each pixel 120 will have to fall by a same relative amount, for example by 1.0 V or any other suitable value, to trip the comparator COMP1.

At time T1, the autozero signals AZ_* may be de-asserted to turn off the HG autozero switch S2, LG autozero switch S3, and comparator autozero switch S4. At time T2, the Vramp signal may be set to its first ramp start voltage level VR(SHR_START). Lowering Vramp can turn on the transistor P1, which can pull signal OUT1 to a higher voltage level, for example to the pixel 120 reset level. At time T2, Vinp may also be lowered to Vinp(trip) from Vinp(AZ) by an amount greater than Vswing-Vgs(P1), where Vswing is the linear full well (LFW) voltage swing of the pixel 120. For example, if the LFW swing is 1.0 V and Vgs(P1)=0.7V, then Vinp may be lowered by at least 1.0 V−0.7 V=0.3 V. The gain select switch S1 continues to be in the HG position.

At time T3, RST may be de-asserted. The Vramp signal may begin ramping up from VR(SHR_START). This first voltage ramp for converting a reset voltage level on the pixel output line 155 is sometimes referred to as an SHR ramp. The positive-going ramp signal continues to increase, crosses VR(AZ), and ends at VR(STOP). The first output signal OUT1 is pulled up to or approximately to the full PIXOUT value when Vramp is at VR(SHR_START), and starts dipping when P1 gets turned off. For example, When the transistor P1 turns off, the column line current source 210 will pull the first output signal OUT1 signal down.

At time T4, the dip in the first output signal OUT1 exceeds the value set by Vinp(trip). At this time, the comparator COMP1 trips and set the latch LAT1, causing the second output signal OUT2 to be asserted. The assertion of the second output signal OUT2 causes the column line switch S6 to turn on and pull the first output signal OUT1 back up to the pixel output level PIXOUT. This allows current to continue flowing through the column line current source 210 even though the transistor P1 is off. The assertion of the second output signal OUT2 also causes the counter 240 to be disabled or otherwise stop counting. The final count value generated by counter 240 at time T4 is thus a function of the reset signal provided by the selected pixel 120. The time from T1 to T4 may be referred to as the SHR ramp phase for normal readout.

At time T5, after the end of the SHR ramp phase, the pixel transfer gate signal (TX) may be asserted. At this time, the PIXOUT signal may initially increase and the Vramp signal may be brought back down to either VR(AZ) if the clamp switch S7 is present as shown at time T6, or otherwise to VR(SHS_START). After time T6, the PIXOUT signal may either stay high as indicated by waveform 405 in a dim light scenario or may begin dropping as indicated by waveform 410 in a bright light scenario.

During this phase, the pixel 120 output voltage may become higher than the pixel reset value due to clock feedthrough of the TX gate. At time T7, the PIXOUT waveform may continue dropping in both the dim light and bright light scenarios. At this time, to quickly discharge the pixel 120 output or otherwise help it settle more quickly to the actual SHS value, the clamp switch S7 may be turned on momentarily. At this time, the Vramp may be at VR(AZ) and the CLAMP_EN signal may be momentarily asserted. During this phase, the HG signal may be de-asserted to prevent the first output signal OUT1 from getting pulled to ground while clamping. The HG signal may be de-asserted, for example, at time T5 or any other suitable time during this phase. The time period from time T5 to T7 may be referred to as the transfer and clamp phase.

At time T8, after the CLAMP_EN signal is de-asserted, the RST and HG signal may be asserted to reset the second output signal OUT2 and connect the gain select switch S1 to the transistor P1. The Vramp signal may be lowered to VR(GS), which may be a predetermined gain selection threshold voltage. In some embodiments, the gain selection threshold voltage may be selected and used as described in U.S. patent application Ser. No. 18/668,363, which is incorporated herein by reference. For example, the VR(GS) level may be set at any suitable voltage for determining whether to convert the SHS pixel value using high gain or low gain. In some embodiments, VR(GS) may be set to about 90 percent, 95 percent, or the like of the ADC 200 full scale when the high gain (P1) is used to measure the SHS pixel value. VR(GS) may be selected to avoid saturating the ADC 200 while allowing high gain to be used in appropriate situations.

At time T9, once the pixel output PIXOUT is reasonably settled, the RST signal may be de-asserted, and the second output signal OUT2 may be checked. If the second output signal OUT2 signal remains low, then the SHS readout of the pixel output line 155 can be converted in high gain mode by continuing to keep the gain select switch S1 in the HG position, similar to the SHR conversion. If the second output signal OUT2 is high, then the voltage swing on the pixel output line 155 is excessive for high gain mode and the SHS conversion has to be converted in low gain mode. Therefore, at time T9, if the second output signal OUT2 is high, then the HG signal is de-asserted to connect the gain select switch S1 to the transistor P2. The period of time from time T9 to T10 may be referred to as the adaptive gain comparison phase.

At time T10, the RST signal may again be asserted briefly, for example to reset the second output signal OUT2. RST is then de-asserted and the Vramp signal may begin ramping up from VR(SHS_START). This second voltage ramp for converting an image voltage level on the pixel output line 155 is sometimes referred to as an SHS ramp. The positive-going ramp signal continues to increase, and ends at VR(STOP). The first output signal OUT1 is pulled up to or approximately to the PIXOUT value when Vramp is at VR(SHS_START), and starts dipping when P1 or P2, whichever is selected by gain select switch S1, turns off.

When RST is de-asserted the counter 240 may begin counting again. In some embodiments, a clock for the counter 240 (not shown) may not start until the voltage ramp begins, at which time the counter output can change. In some embodiments, the counter 240 may be reset prior to time T10 to help distinguish between the SHR count value and the SHS count value. In some embodiments, the counter 240 may have its bits inverted prior to time T10 or any other suitable time to carry out the subtraction of the SHR count value from the SHS count value. For example, if the counter 240 counted upward for the SHR readout, then the counter 240 may, for the SHS readout, count down from the SHR value.

In the bright light scenario, the transistor P2 may be turned off at time T11. When the transistor P2 is turned off at time T11, the first output signal OUT1 will fall below the Vinp(trip) threshold. This will cause the comparator COMP1 to trip, causing the second output signal OUT2 to be asserted as shown by the waveform 420. Asserting the second output signal OUT2 can stop the counter 240 from counting further. The final count value generated by the counter 240 at time T11 is thus a function of the bright signal value read out from the selected pixel 120.

In the dim light scenario, the transistor P1 may be turned off at time T12. When the transistor P1 is turned off at time T12, the first output signal OUT1 will fall below the Vinp(trip) threshold. This will cause the comparator COMP1 to trip, causing the second output signal OUT2 to be asserted as shown by the waveform 415. Asserting the second output signal OUT2 can stop the counter 240 from counting further. The final count value generated by the counter 240 at time T12 is thus a function of the dim signal value read out from the selected pixel 120. After time T11 and/or T12, the Vramp signal may continue to increase until it reaches the ramp stop voltage level VR(STOP). The time from T10 to the end of the SHS ramp may be referred to as the SHS ramp phase for normal readout. In some embodiments, some columns of the image sensor 100 may be operating in high gain mode and other columns may be operating in low gain mode, depending on the signal level of each column.

As described above, the counter 240 may start counting from the start of each of the SHR ramp and SHS ramp. In some embodiments, the SHR ramp and SHS ramp may start at the same voltage value. For example, VR(SHR_START) may equal VR(SHS_START). In such embodiments, the counter 240 values for SHR and SHS may be simply subtracted to determine the actual image value for the pixel 120.

In some embodiments, the SHR ramp may start at a higher voltage than the SHS ramp because the reset level is fairly well controlled and a full Vramp swing is not needed. In such cases, the counter 240 values for the same voltage will be different between the two ramp phases, in other words separated by an offset. The voltage generator 250 may use a digital-to-analog converter (DAC) to produce well-determined ramp voltages, where the output voltage of the DAC is determined by the digital code at its input. The difference, or offset, between the start of the SHR ramp and SHS ramp may be determined by subtracting the respective start codes for each ramp. The subtraction of the counter 240 value determined by the SHR ramp and the counter 240 value determined by the SHS ramp may be modified by the determined offset to determine the final image value of the pixel 120.

If the SHS ramp phase was performed using high gain, for example with the transistor P1 selected, then the final pixel value calculation may be performed using the subtraction mentioned above, whether or not requiring an offset. If the SHS ramp phase was instead performed using low gain, for example with the transistor P2 selected, then a calibration may be performed to adjust the SHR value and/or SHS value based on the respective gain for each readout. For example, in some embodiments, the SHS value may be corrected by determining a ratio between the gain used for the SHS ramp and SHR ramp, for example the ratio between the gain of transistor P1 and transistor P2. The ratio between the gains may be determined by performing one or more calibration reads before the frame readout, with one or more predetermined input values in place of the pixel output. Exemplary devices and methods for performing such calibration, gain ratio calculation, and readout value correction are described in U.S. patent application Ser. No. 18/668,363, which is incorporated herein by reference.

Advantageously, the comparator COMP1 trips upon the dip magnitude of the first output signal OUT1 from the first comparison stage 220 rather than upon crossing an absolute threshold. This trip behavior, along with the described auto-zeroing of the second comparison stage 230, provides better performance at the switchover point for adaptive gain due to less dependency on the pixel 120 SHR value.

FIG. 5 is a timing diagram illustrating the operation of the ADC circuit 200 when the image sensor 100 performs a reverse readout. Waveform PIX_RST represents the signal for controlling the reset transistor T2, as illustrated in FIG. 2. Waveform PIXOUT represents the voltage at the pixel output line 155. Because the SHS readout is performed first in the reverse readout mode, the control signal for the charge transfer transistor T1 is not illustrated as the charge transfer may be assumed to have occurred prior to the events illustrated in FIG. 5, causing the PIXOUT signal to be high as indicated by waveform 505 in a dim light scenario or to be low as indicated by waveform 510 in a bright light scenario.

Waveforms AZ_LG and AZ_HG represent the signals for activating the autozero switches S3 and S2, respectively. Waveform AZ_2 represents the signal for activating the comparator autozero switch S4. Waveform CLAMP_EN represents the signal for activating the clamp switch S7. Waveform RST represents the reset control signal provided to the ADC circuit 200. Waveform HG represents the HG control signal indicating whether the first comparison stage 220 is operating in a high-gain mode. Waveform RR represents the RR control signal indicating whether the ADC circuit 200 is operating in reverse readout mode. The RR signal may be asserted for the entirety of the reverse readout or at least the portions thereof shown in FIG. 5. Waveform Vramp represents the ramp signal output from the ramp generator 250 and/or the ramp signal provided by the ramp bias circuit 330, for example from node 355. Waveform OUT2 represents the signal output by the second comparison stage 230, for example used to selectively enable and disable the counter 240.

The reverse readout operations may perform the SHS readout prior to the SHR readout. Auto-zeroing may be performed prior to time T1. Auto-zeroing will be performed for SHS readout, where the voltage of the SHS pixel readout may vary significantly more compared to the reset voltage for SHR, depending on illumination. In some embodiments, it may be difficult to perform auto-zeroing with transistor P1 or transistor P2 in diode-connected mode as is done with the normal readout mode described above. For example, if the PIXOUT voltage for the SHS readout is 1.0 V (high illumination), the Vgs(P1) or Vgs(P2) is 0.7 V, then the drain of transistor P1 and/or transistor P2 will be approximately 300 mV. This low voltage at the drain of the respective transistor will cause the column line current source 210 to enter into a triode region, further causing pixel output line 155 current to drop.

Prior to time T1, then, the autozero of the adaptive gain circuit 320 may be based on PIXOUT in a manner that keeps the column line current source 210 operating appropriately. In some embodiments, the autozero signal AZ_LG may be asserted to turn on the LG autozero switch S3. The AZ_HG autozero signal may be asserted to turn on the HG autozero switch S2, or may remain de-asserted to keep the HG autozero switch S2 off. At this time, the RST signal may be asserted, turning on the column line switch S6 via the column line level setting circuit 310, for example due to the output of the first AND gate AND1 being asserted. The first output signal OUT1 voltage and the voltage at the gate of the transistor P2 will be the same as the PIXOUT voltage.

Unlike the normal readout mode where the transistor P1 is biased on during the autozero phase, the transistor P2 will remain off because there may not be sufficient voltage headroom to bias it as described just above. Accordingly, because the column line switch S6 is on, even if the PIXOUT voltage drops low due to the pixel 120 receiving substantial illumination, for example to 800 mV, then the column line current source 210 will remain in a desired operating condition. Further, the auto-zero value of the transistor P2 will be offset by zero volts instead of by the Vgs(P2) as is the case with the normal readout described with respect to FIG. 4. The ramp voltage Vramp may be set to VR(RR_AZ) during this time. In some embodiments, VR(RR_AZ) may be higher compared to VR(AZ) for the normal readout (see FIG. 4) because, after performing the autozeroing, Vramp may need to be lowered by, or more than, Vgs(P2) to allow the transistor P2 to turn on at the beginning of the ramp phase.

In some embodiments, the reverse readout may be performed in low-gain mode only, with gain select switch S1 always connected to the transistor P2. For the entirety of the reverse readout operations illustrated in FIG. 5, the RR signal may be asserted and the HG signal may be de-asserted. FIG. 5 thus illustrates an embodiment of a method of performing a fixed-gain reverse readout 500. In addition, because reverse readout may be performed without adaptive gain, the comparator COMP1 may be provided with a fixed Vinp(RR) threshold voltage (not shown) and the comparison mode switch S5 may remain on, shorting the capacitor C4 from the circuit and causing the comparator COMP1 to trip at the absolute voltage Vinp(RR). In some embodiments, the Vinp(RR) level may be chosen to be less than the lowest SHS voltage that can be expected to saturate the ADC 200 in reverse readout. For example, Vinp(RR) can be 550 mV, 600 mV, 650 mV, 700 mV, 750 mV, 800 mV, 850 mV, 900 mV, 1.0V, or the like. The AZ_2 signal may remain de-asserted for the entirety of the reverse readout so that the comparator autozero switch S4 remains off and the comparator COMP1 is not auto-zeroed.

At time T1, the autozero signals which are asserted, for example AZ_LG and AZ_HG, may be de-asserted to turn off the respective autozero switches. At time T2, the Vramp signal may be set to a ramp start voltage level VR(RR_START). The voltage VR(RR_START) may be lower than VR(RR_AZ) by at least Vgs(P2) so that P2 is turned on initially. In some embodiments, VR(RR_START) for reverse readout may be the same as VR(SHS_START) for normal readout. At time T3, RST may be de-asserted. The Vramp signal may begin ramping up from VR(RR_START). This first voltage ramp for converting an image level on the pixel output line 155 is sometimes referred to as an SHS ramp. The positive-going ramp signal continues to increase and ends at VR(RR_SHS_STOP). Due to the autozeroing of the transistor P2, the SHS ramp may only need to span a few hundred millivolts, for example similar to or the same as the SHR ramp in normal readout.

At time T4, during the SHS ramp, the transistor P2 will turn off causing the first output signal OUT1 to fall below Vinp(RR) and causing the comparator COMP1 to trip. As the first output signal OUT1 falls, the column line current source 210 will remain saturated. When the comparator COMP1 trips, the latch LAT1 will be set and the second output signal OUT2 will be asserted. The assertion of the second output signal OUT2 causes the column line switch S6 to turn on and pull the first output signal OUT1 back up to the pixel output level PIXOUT. This allows current to continue flowing through the column line current source 210 even though the transistor P2 is off. The assertion of the second output signal OUT2 also causes the counter 240 to be disabled or otherwise stop counting. The final count value generated by counter 240 at time T4 is thus a function of the image signal provided by the selected pixel 120. The time from T1 to T4 may be referred to as the SHS ramp phase for reverse readout.

At time T5, the pixel reset signal PIX_RST may be asserted to clear the charge accumulated at the floating diffusion node FD (see FIG. 2). Depending on the illumination prior to the SHS readout, the pixel 120 output voltage on the pixel output line 155 will have a positive swing, reaching its full reset value at some time thereafter, for example at time T6. In some embodiments, the clamp switch S7 is not activated during reverse readout. At time T6, the Vramp signal may be set to the ramp start voltage level VR(RR_START), which may be the same used for the SHS ramp phase. At time T7, the PIX_RST signal may be de-asserted. The time period from T5 to T7 may be referred to as the pixel reset phase.

At time T8, the RST signal is briefly asserted to reset the second output signal OUT2. At time T9, RST may be de-asserted and the Vramp signal may begin ramping up from VR(RR_START). This second voltage ramp for converting a reset level on the pixel output line 155 is sometimes referred to as an SHR ramp. At this time, the counter 240 may begin counting again. The positive-going ramp signal continues to increase and ends at VR(RR_SHR_STOP). In some embodiments, VR(RR_SHR_STOP) in reverse readout may be the same as VR(STOP) in normal readout. The first output signal OUT1 is pulled up to or approximately to the PIXOUT value when Vramp is at VR(RR_START), and starts dipping when the transistor P2 turns off. The time from T9 to the end of the SHR ramp may be referred to as the SHR ramp phase for reverse readout. In some embodiments, the SHR ramp for reverse readout may be the same as or similar to the SHS ramp for normal readout, for example sufficient to span the pixel swing for the LFW of the pixel 120.

In some embodiments, the starting voltage level for the SHS ramp and SHR ramp may be the same, and the ending ramp voltage levels may differ. The SHR ramp may span a broader range of voltages than the SHS ramp. As noted above, the SHS ramp may only span a few hundred millivolts due to the autozeroing. For example, a bright image value of 1.0 V on the pixel output line 155 may be in the middle of the SHS ramp, and the approximately 2.0 V reset value may trip the comparator COMP1 higher on the SHR ramp as represented by waveform 520 at time T11. For further example, if the auto-zero was done with a dim image value of about 2.0 V, this value may again be in the middle of the SHS ramp and the approximately 2.0 V reset value would trip the comparator COMP1 earlier in the SHR ramp as represented by waveform 515 at time T10. Because both the SHR and SHS ramp start at the same voltage level, no offset is required for the final pixel value calculation.

In some embodiments, the counter 240 may be reset prior to time T9 to help distinguish between the SHS count value and the SHR count value. In some embodiments, the counter 240 may have its bits inverted prior to time T9 or any other suitable time to carry out the subtraction of the SHR count value from the SHS count value. Therefore, in some embodiments, the counter 240 may count in the opposite direction for the SHR ramp compared to the SHS ramp, and the final count value provides the final pixel 120 value for the reverse readout mode.

Advantageously, the inclusion of the column line switch S6 provides better headroom for the pixel 120 output and provides the capability to perform reverse readout as well as adaptive gain normal readout. Further, in comparison to other solutions, a readout circuitry 150 according to the embodiments described herein may only require one SHR conversion and one ramp ADC and may provide faster frame rates.

Advantageously, the incremental power consumed by the embodiments described herein is very low, since the low noise first comparison stage 220 sits in the pixel output line 155 current path used to bias the pixel 120 source follower. The second comparison stage 230 may be less critical and can be designed for very low power.

The various components and functions shown and described with respect to the process flows and image sensor may be distributed amongst the various components of the image sensor 100 and/or external systems in any manner, and different embodiments may organize the processing of various features and information in any number of different ways. Several of the various features and systems described herein may be implemented in software and/or firmware that resides in non-transitory data storage for execution by one or more processors to perform the various (automated) processes described herein. For example, the various timing, control, calculation, and/or other circuitry of the image sensor 100 may be implemented using a processor, transistor logic, a field programmable gate array (FPGA), state machine, and/or the like.

The arrangement of the pixel 120, ADC circuit 200, image sensor 100, and the like as described herein are merely illustrative. In general, any desired pixel circuitry may be used with the readout circuitry 150. The pixel circuitry may include an anti-blooming transistor, one or more multi-gain transistors and/or storage nodes, and the like. The ADC circuit 200 and respective circuitry and methods may be used in an image sensor that operates with a rolling shutter (in which each row of pixels sequentially captures an image) or a global shutter (in which every pixel in the image sensor simultaneously captures an image), with CMOS image sensors, indirect time-of-flight (iToF) image sensors, and/or the like. The ADC circuit 200 may further be used in other sensing devices and applications.

It will be recognized that various circuitry described herein may alternatively or additionally be implemented as computer instructions (software, firmware, or the like) configured to cause a processor to perform the functions of the described circuitry. It will also be recognized that computer instructions and/or automated processes described herein may alternatively or additionally be implemented as hardware circuitry operable to perform the functions of the described computer instructions. Further, various components may be described or illustrated as coupled, and, unless stated otherwise, electrical coupling, communicative coupling, and/or the like may include direct coupling and/or indirect coupling of components.

The general concepts set forth herein may be adapted to any number of alternate but equivalent embodiments. The term “exemplary” is used herein to represent one example, instance or illustration that may have any number of alternates. Any implementation described herein as “exemplary” is not necessarily to be construed as preferred or advantageous over other implementations, nor is it necessarily intended as a model that must be duplicated in other implementations. While several exemplary embodiments have been presented in the foregoing detailed description, it should be appreciated that a vast number of alternate but equivalent variations exist, and the examples presented herein are not intended to limit the scope, applicability, or configuration of the invention in any way. On the contrary, various changes may be made in the function and arrangement of elements described without departing from the scope of the claims and their legal equivalents.

What is claimed is:

1. An image sensor, comprising:
a pixel;
a pixel output line coupled to the pixel; and
an analog-to-digital converter (ADC) coupled to the pixel output line, wherein the ADC is reconfigurable to operate in a normal readout mode and a reverse readout mode, wherein the ADC comprises:
a first comparison stage comprising an adaptive gain circuit coupled with the pixel output line and a ramp voltage signal, wherein the first comparison stage is operable to generate a first output signal in response to the ramp voltage signal and a pixel output value from the pixel output line;
a second comparison stage operable to receive the first output signal and generate a second output signal based on a comparison of the first output signal to a threshold voltage level; and
a counter controllable according to the second output signal of the second comparison stage.

2. The image sensor of claim 1, wherein:
in the normal readout mode, the ADC is operable to perform an adaptive gain readout of the pixel; and
in the reverse readout mode, the ADC is operable to perform a fixed gain readout of the pixel.

3. The image sensor of claim 1, further comprising a column line current source coupled to the pixel output line, wherein the first comparison stage is coupled in series between the pixel and the column line current source.

4. The image sensor of claim 1, wherein:
in the normal readout mode, the ADC is operable to perform a sample-and-hold reset (SHR) readout followed by a sample-and-hold signal (SHS) readout; and
in the reverse readout mode, the ADC is operable to perform the SHS readout followed by the SHR readout.

5. The image sensor of claim 4, wherein:
in the normal readout mode, the ADC is operable to perform a high-gain SHR readout and an adaptive gain SHS readout; and
in the reverse readout mode, the ADC is operable to perform a low-gain SHS readout and a low-gain SHR readout.

6. The image sensor of claim 1, wherein, in the normal readout mode, the ADC is operable to:
perform an auto-zero of the first comparison stage and the second comparison stage;
perform a SHR ramp phase after the auto-zero of the first and second comparison stages;
determine a reset value of the pixel based on the SHR ramp phase;
perform an adaptive gain comparison phase after a transfer phase of the pixel;
select a gain for a SHS ramp phase based on the adaptive gain comparison phase;
perform a SHS ramp phase using the selected gain; and
determined an image value of the pixel based on the SHS ramp phase.

7. The image sensor of claim 1, wherein, in the reverse readout mode, the ADC is operable to:
perform an auto-zero of the first comparison stage after a transfer phase of the pixel;
perform a SHS ramp phase after the auto-zero of the first comparison stage;
determine an image value of the pixel based on the SHS ramp phase;
perform a SHR ramp phase after the SHS ramp phase, wherein the SHR ramp phase is performed after a reset phase of the pixel; and
determine a reset value of the pixel based on the SHS ramp phase.

8. An analog-to-digital converter (ADC) coupled with a pixel via a pixel output line, the ADC comprising:
a first comparison stage, comprising:
a first output; and
an adaptive gain circuit coupled with a voltage ramp signal, the pixel output line, and the first output, wherein:
the adaptive gain circuit comprises a high-gain transistor, a low-gain transistor, and a ramp attenuation circuit coupled with the voltage ramp signal and the high-gain transistor;
the adaptive gain circuit is operable to perform a first comparison, using one of the low-gain transistor or high-gain transistor, of the voltage ramp signal with a pixel output value on the pixel output line; and
the first comparison stage is operable to provide a first output signal on the first output based on the first comparison;
a second comparison stage coupled with the first output, the second comparison stage comprising a second output, wherein the second comparison stage is operable to provide a second output signal on the second output based on a second comparison of the first output signal to a threshold voltage; and
a counter controllable according to the second output.

9. The ADC of claim 8, wherein:
the second comparison stage comprises a comparator having a first input, a second input, and a third output;
the first input is coupled with the first output of the first comparison stage;
the second input is coupled to receive the threshold voltage; and
the second comparison stage is operable to determine the second output signal based on the third output.

10. The ADC of claim 9, wherein the second comparison stage is operable to selectively auto-zero the comparator.

11. The ADC of claim 8, wherein the adaptive gain circuit is controllable to select the high-gain transistor or the low-gain transistor for the first comparison.

12. The ADC of claim 8, wherein the first comparison stage is operable to selectively auto-zero the adaptive gain circuit.

13. The ADC of claim 8, wherein the ADC is reconfigurable to operate in a normal readout mode and a reverse readout mode, and wherein:
in the normal readout mode, the first and second comparison stages are operable to perform a sample-and-hold reset (SHR) readout followed by a sample-and-hold signal (SHS) readout; and
in the reverse readout mode, the first and second comparison stages are operable to perform the SHS readout followed by the SHR readout.

14. The ADC of claim 13, wherein:
the first and second comparison stages are operable, in a normal readout mode, to perform an adaptive gain readout of the pixel; and
the first and second comparison stages are operable, in a reverse readout mode, to perform a fixed gain readout of the pixel.

15. The ADC of claim 14, wherein:
the second comparison stage is operable, during the normal readout mode, to compare the first output signal with a gain selection voltage threshold; and
the adaptive gain circuit is controllable to select the high-gain transistor or the low-gain transistor based on the first comparison to the gain selection voltage threshold.

16. The ADC of claim 8, further comprising:
a column line switch having a first terminal coupled with the pixel output line and a second terminal coupled with the first output of the first comparison stage; and
a column line level setting circuit operable to control the column line switch.

17. A method for converting a pixel output signal of a pixel, comprising:
receiving, by a first comparison stage of an analog-to-digital converter (ADC), the pixel output signal and a ramp voltage signal;
selecting a gain level of the first comparison stage;
performing a first comparison, by the first comparison stage and according to the selected gain level, of the pixel output signal to the ramp voltage signal;
generating a first output signal based on the first comparison;
performing a second comparison, by a second comparison stage of the ADC, of the first output signal to a threshold voltage level;
generating, by the second comparison stage, a second output signal based on the second comparison; and
controlling a counter based on the second output signal.

18. The method of claim 17, further comprising:
in a normal readout mode, adaptively selecting the gain level based on the pixel output signal; and
in a reverse readout mode, selecting a low-gain level.

19. The method of claim 17, further comprising:
in a normal readout mode, performing a sample-and-hold reset (SHR) readout followed by a sample-and-hold signal (SHS) readout; and
in a reverse readout mode, performing the SHS readout followed by the SHR readout.

20. The method of claim 19, further comprising:
in the normal readout mode, selecting a high-gain level for the SHR readout; and
in the normal readout mode, adaptively selecting the gain level for the SHS readout.
